(19) United States
(12) Patent Application Publication
(10) Pub. No.: US 2025/0077118 A1
(43) Pub. Date: Mar. 6, 2025

(54) MEMORY CONTROLLER PERFORMING TWO-STEP PROGRAM OPERATION, STORAGE DEVICE INCLUDING THE SAME, AND OPERATION METHOD THEREOF

(71) Applicant: SAMSUNG ELECTRONICS CO., LTD., Suwon-si (KR)

(72) Inventors: Suyong LEE, Suwon-si (KR); Seona WON, Suwon-si (KR); Jinwoo HONG, Suwon-si (KR)

(73) Assignee: SAMSUNG ELECTRONICS CO., LTD., Suwon-si (KR)

(21) Appl. No.: 18/598,754

(22) Filed: Mar. 7, 2024

(30) Foreign Application Priority Data
Aug. 31, 2023 (KR) 10-2023-0115411

(51) Int. Cl. G06F 3/06

(52) U.S. Cl. CPC G06F 3/0659; G06F 3/0619; G06F 3/0656; G06F 3/0679

(57) ABSTRACT

A storage device includes a memory device configured to store data; a single-level cell (SLC) buffer configured temporarily to store data to be stored in the memory device; and a memory controller configured to control read operations or write operations of the memory device and the SLC buffer, wherein the memory controller is further configured to perform a first program operation to SLC program a first page to first memory cells of the memory device based on a host write request, store at least one second page to the SLC buffer, and perform, during an idle time, a second program operation of programming the at least second page stored in the SLC buffer to the first memory cells.

### CROSS-REFERENCE TO RELATED APPLICATION(S)

This application claims priority under 35 U.S.C. § 119 to Korean Patent Application No. 10-2023-0115411 filed on Aug. 31, 2023, in the Korean Intellectual Property Office, the disclosures of which are incorporated by reference herein in their entireties.

### BACKGROUND

The present disclosure relates to a semiconductor memory device, and more particularly, relate to a memory device performing a two-step program operation.

A semiconductor memory may be mainly classified as a volatile memory or a non-volatile memory. Read and write speeds of the volatile memory (e.g., DRAM or SRAM) are fast, but the data stored in the volatile memory disappear when a power is turned off. In contrast, the non-volatile memory may retain data even when the power is turned off.

A representative example of the non-volatile memory is a flash memory. The flash memory may store multi-bit data of two or more bits in one memory cell. The flash memory that stores the multi-bit data may have one erase state and a plurality of program states depending on threshold voltage distributions.

Triple-level cell (TLC) flash memory may store three bits of data in one memory cell. A storage device based on the flash memory may use a single-level cell (SLC) buffer to improve write performance of the TLC flash memory. However, because the SLC buffer performs the SLC program, the allocated storage space may be consumed quickly. If the storage space of the SLC buffer is used up, the write performance of the flash storage device may deteriorate. Additionally, because the SLC buffer performs frequent Program-Erase cycles, it may also affect the usage life of the storage device.

### SUMMARY

Example embodiments of the present disclosure provide a memory controller and storage device that reduces the page usage rate and block erase count of the SLC buffer by using the SLC buffer more efficiently through a two-step program operation.

According to an aspect of an example embodiment, a storage device includes: a memory device configured to store data; a single-level cell (SLC) buffer configured temporarily to store data to be stored in the memory device; and a memory controller configured to control read operations or write operations of the memory device and the SLC buffer, wherein the memory controller is further configured to perform a first program operation to SLC program a first page to first memory cells of the memory device based on a host write request, store at least one second page to the SLC buffer, and perform, during an idle time, a second program operation of programming the at least second page stored in the SLC buffer to the first memory cells.

According to an aspect of an example embodiment, a memory controller that controls an operation of a memory device and a single-level cell (SLC) buffer, includes: a first interface connected to a host; a second interface connected to the memory device; and a third interface connected to the SLC buffer, wherein the memory controller is further configured to: receive a write request from the host through the first interface, SLC program a first page to first memory cells of the memory device through the second interface, store at least second page to the SLC buffer through the third interface, and program the at least second page stored in the SLC buffer to the first memory cells during an idle time.

According to an aspect of an example embodiment, a method for operating a storage device which includes a memory device for storing data, a single-level cell (SLC) buffer configured to temporarily store data to be stored in the memory device, and a memory controller configured to control read operations or write operations of the memory device and the SLC buffer, includes: receiving a write request from a host and SLC programming a first page to first memory cells of the memory device; storing, to the SLC buffer, at least second page; and triple-level cell (TLC) programming the at least second page stored in the SLC buffer to the first memory cells during an idle time.

### BRIEF DESCRIPTION OF THE FIGURES

The above and other aspects and features of the present disclosure will become apparent by describing in detail embodiments thereof with reference to the accompanying drawings, in which:

FIG. 1 is a block diagram illustrating a user device according to one or more example embodiments of the present disclosure;

FIG. 2 is a block diagram illustrating as an example embodiment of the memory device illustrated in FIG. 1;

FIG. 3 is a circuit diagram illustrating an example embodiment of a memory block BLK1 of the memory cell array illustrated in FIG. 2;

FIG. 4 is a circuit diagram illustrating cell strings selected by the first string selection line SSL1 from among the cell strings of the memory block BLK1 illustrated in FIG. 3;

FIG. 5 is a diagram illustrating an example embodiment of threshold voltage distributions of memory cells illustrated in FIG. 4;

FIG. 6 is a conceptual diagram illustrating a method of operating the storage device shown in FIG. 1;

FIGS. 7 and 8 are flowcharts illustrating a method of operating the storage device shown in FIG. 6;

FIG. 9 is a conceptual diagram illustrating a TLC programming method of the storage device shown in FIG. 1;

FIG. 10 is a flowchart illustrating a method of operating the storage device shown in FIG. 9;

FIGS. 11 and 12 are diagrams illustrating an example embodiment of the first program operation shown in FIG. 9 and threshold voltage distribution;

FIGS. 13 and 14 are diagrams illustrating an example embodiment of the second program operation shown in FIG. 9 and threshold voltage distribution;

FIG. 15 is a conceptual diagram illustrating another example embodiment of a TLC program operation of the storage device shown in FIG. 1;

FIG. 16 is a conceptual diagram illustrating the difference between the TLC program method shown in FIG. 9 and the TLC program method shown in FIG. 15;

FIGS. 17 and 18 are conceptual diagrams illustrating another example embodiment of the difference between the TLC program method shown in FIG. 9 and the TLC program method shown in FIG. 15;

FIG. 19 is a conceptual diagram illustrating a data recovery method when a sudden power-off occurs during a second program operation of the storage device shown in FIG. 9;

FIGS. 20 and 21 are graph and diagram illustrating threshold voltage distribution and program ordering of a storage device that performs a two-step program operation;

FIG. 22 is a diagram illustrating an example embodiment of a flash memory having a multi-stack structure; and

FIG. 23 is a block diagram illustrating an example in which a storage device according to an embodiment of the present disclosure is implemented with a solid state drive (SSD).

### DETAILED DESCRIPTION

Below, example embodiments of the present disclosure will be described in detail and clearly to for implementation.

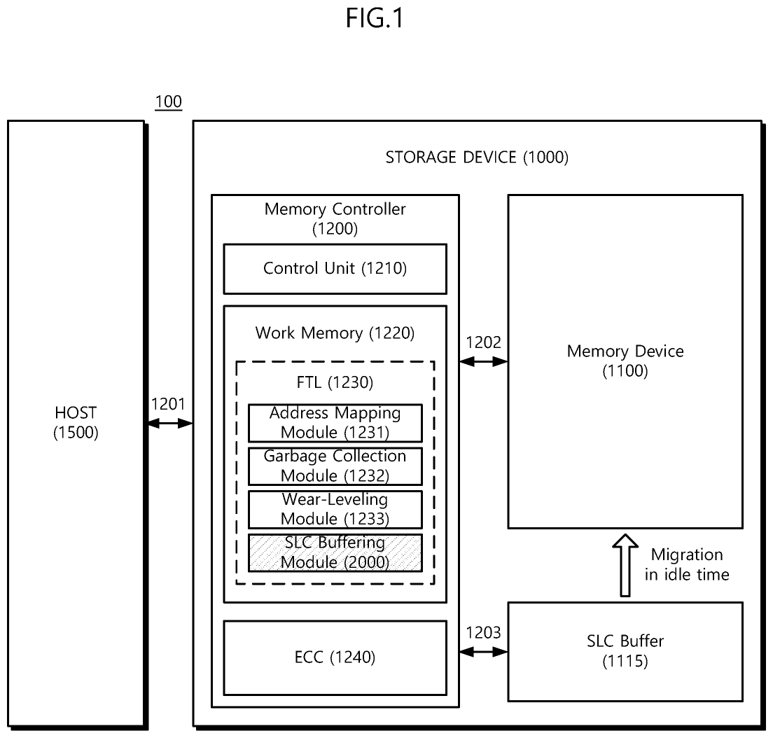

FIG. 1 is a block diagram illustrating a user device according to one or more example embodiments of the present disclosure. Referring to FIG. 1, the user device 100 may include a storage device 1000 and a host 1500. The storage device 1000 and the host 1500 may be connected through a host interface 1201. The host interface 1201 may be a standard interface such as an Advanced Technology Attachment (ATA) interface, a Serial Advanced Technology Attachment (SATA) interface, a Parallel Advanced Technology Attachment (PATA) interface, a Universal Serial Bus (USB) interface, a Small Computer System Interface (SCSI), an Enhanced Small Disk Interface (ESDI), an IEEE 1394 interview, an Integrated Drive Electronics (IDE) interface, a card interface, etc.

The storage device 1000 may include a memory device 1100, a single-level cell (SLC) buffer 1115, and a memory controller 1200. The memory device 1100 and the SLC buffer 1115 may be non-volatile memory such as flash memory or phase change memory (PRAM). When the memory device 1100 is a flash memory, the storage device 1000 may be a flash storage device based on flash memory. For example, the storage device 1000 may be a Solid State Drive (SSD), a Universal Flash Storage (UFS), memory card, etc.

The memory device 1100 may be connected to the memory controller 1200 through a memory interface 1202. The memory device 1100 may include a memory cell array and a peripheral circuit. The peripheral circuitry may include all analog or digital circuits required to store or read data in the memory cell array.

The peripheral circuit may receive external power from the memory controller 1200 and generate various levels of internal power. The peripheral circuit may receive commands, addresses, and data from the memory controller 1200, and store the data in the memory cell array according to the control signals. Additionally, the peripheral circuit may read data stored in the memory cell array and provide the data to the memory controller 1200.

The memory cell array may include a plurality of memory blocks. Each memory block may have a vertical three-dimensional structure. Each memory block may include a plurality of memory cells. Multi-bit data may be stored in each memory cell. For example, the memory device 1100 may be a TLC flash memory capable of storing 3 bits of data in one memory cell.

The memory cell array may be located next to or above the peripheral circuit due to the design arrangement structure. The structure in which the memory cell array is located above the peripheral circuit is called a COP (cell on peripheral) structure. The memory cell array may be manufactured as a separate chip from the peripheral circuit. The upper chip including the memory cell array and the lower chip including the peripheral circuit may be connected to each other using a bonding method. This structure is called C2C (chip to chip) structure.

The SLC buffer 1115 may be connected to the memory controller 1200 through a buffer interface 1203. The SLC buffer 1115 may be the same type or different type as the memory device 1100. For example, the memory device 1100 and the SLC buffer 1115 may be the same type of flash memory.

The memory device 1100 may be a TLC flash memory, and the SLC buffer 1115 may be an SLC flash memory. TLC flash memory may store three bits of data in one memory cell, and SLC flash memory may store one bit of data in one memory cell.

The SLC buffer 1115 may be used to temporarily store data to be stored in or read from the memory device 1100. The SLC buffer 1115 may be implemented with non-volatile memory such as flash memory or resistive memory. The SLC buffer 1115 may be included in the memory device 1100 or the memory controller 1200.

The memory controller 1200 may be connected between the memory device 1100 and the host 1500. Additionally, the memory controller 1200 may be connected between the SLC buffer 1115 and the host 1500. The memory controller 1200 may control read or write operations of the memory device 1100 and/or the SLC buffer 1115 in response to a request from the host 1500. The memory controller 1200 may receive host data from the host 1500 and provide it to the memory device 1100 and/or the SLC buffer 1115.

The memory controller 1200 may include a control unit 1210 and a work memory 1220. The control unit 1210 may control overall operations of the memory controller 1200. For example, the control unit 1210 may control a flash translation layer (FTL) to perform an address mapping operation. The control unit 1210 may be a commercially available or custom microprocessor.

The work memory 1220 may be cache memory (e.g., SRAM). The work memory 1220 may serve as a buffer memory (e.g., DRAM) that temporarily stores data. Additionally, the work memory 1220 may be a driving memory of the memory controller 1200. The work memory 1220 may drive a flash translation layer (FTL) 1230.

The FTL 1230 may be firmware or a program for efficiently managing the memory device 1100. The memory device 1100 may not support an overwrite function. Therefore the memory device 1100 may perform the following process while updating data written to the page. First, the memory device 1100 may copy all valid data in the first memory block to which the written page belongs to an empty second memory block. Second, the memory device 1100 may erase the first memory block and make it an empty memory block.

The memory device 1100 may perform a large number of page copy operations (e.g., page read and write) and erase operations while going through this process. The FTL 1230 may be used between the host 1500 and the memory device 1100 to reduce the number of page copy and erase operations. The FTL 1230 may include an address mapping module 1231, a garbage collection module 1232, and a wear leveling module 1233.

The address mapping module 1231 may perform address mapping operations on a page-by-page or block-by-block basis. The page address mapping operation is an operation that converts a logical page address received from the file system into a physical page address in the flash memory 1100. For this purpose, a page-level address mapping table must be maintained in the work memory 1220. The page address mapping operation may provide excellent garbage collection performance, but require a large address mapping table.

The garbage collection module 1232 may perform a garbage collection operation by referring to the address mapping table. The garbage collection module 1232 may use an address mapping table to secure one or more free blocks. The garbage collection module 1232 may move one or more valid data stored in a source block to a target block using the address mapping table. The garbage collection module 1232 may make a free block by erasing the source block to which all valid data has been moved.

The wear-leveling module 1233 may manage the wear-level of memory cells of the flash memory 1100. Memory cells may be deteriorated by write and erase operations, etc. Deteriorated memory cells may cause defects. The wear-leveling module 1233 may prevent specific cell areas from wearing out faster than other cell areas by managing program-erase cycles for the memory cell array. The wear-leveling module 1233 may control the address mapping module 1231 so that program and erase times are equally assigned to cell areas of the memory cell array.

The FTL 1230 may include an SLC buffering module 2000. The SLC buffering module 2000 may receive a write request for a plurality of pages from the host 1500 and perform a write operation of the storage device 1000. The write operation of the storage device 1000 may be largely divided into a host write operation and a migration operation.

During the host write operation, the SLC buffering module 2000 may perform a first program operation to SLC program the first page in a memory block of the memory device 1100. The SLC buffering module 2000 may store at least one second page in the SLC buffer 1115. During the migration operation, the SLC buffering module 2000 may perform a second program operation to TLC program at least one second page written in the SLC buffer 1115 to a memory block of the memory device 1100.

The storage device 1000 according to example embodiments of the present disclosure may perform a two-step program (SLC program and TLC program) using the SLC buffering module 2000. The storage device 1000 according to example embodiments of the present disclosure may reduce page usage of the SLC buffer 1115 by about 33% based on a TLC program through a two-step program method. In addition, the storage device 1000 according to example embodiments of the present disclosure may reduce the block erase operation of the SLC buffer 1115 by about 33% based on the TLC program through a two-step program method.

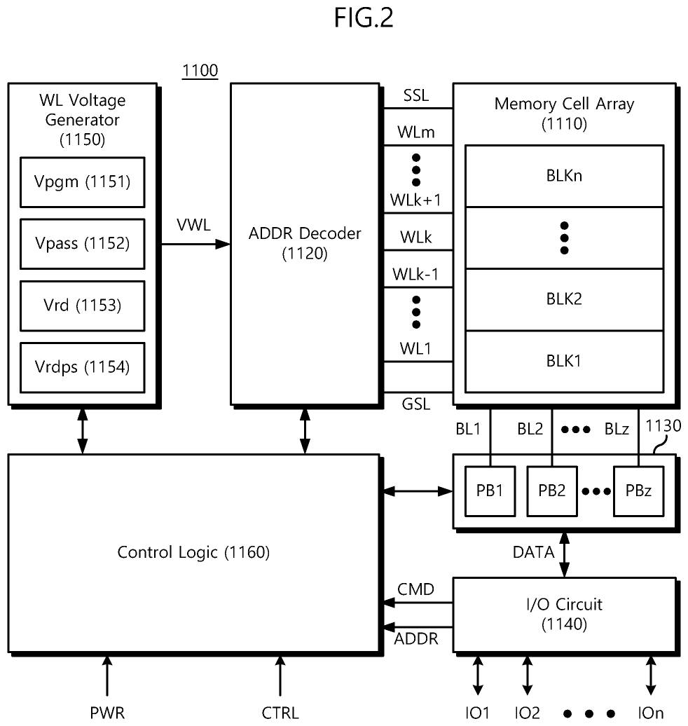

FIG. 2 is a block diagram illustrating as an example embodiment of the memory device illustrated in FIG. 1. The storage device 1000 of FIG. 1 may be a flash storage device based on flash memory. For example, the storage device 1000 may be implemented as an SSD, UFS, memory card, etc.

Referring to FIGS. 1 and 2, the memory device 1100 may include a memory cell array 1110 and a peripheral circuit 1115. The peripheral circuit 1115 may include an address decoder 1120, a page buffer circuit 1130, an input/output circuit 1140, a word line voltage generator 1150, and control logic 1160.

The memory cell array 1110 may include a plurality of memory blocks BLK1 to BLKn. Each memory block may be composed of a plurality of pages. Each page may include a plurality of memory cells. Each memory cell may store multi-bit data (e.g., two or more bits). Each memory block may correspond to an erase unit, and each page may correspond to a read and/or write unit.

The memory cell array 1110 may be formed in a direction perpendicular to a substrate. A gate electrode layer and an insulation layer may be alternately deposited on the substrate. Each memory block (e.g., BLK1) may be connected to one or more string selection lines SSL, a plurality of word lines WL1 to WLm, and one or more ground selection lines GSL. WLk is a selected word line sWL and the remaining word lines (WL1 to WLk−1, WLk+1 to WLm) are unselected word lines uWL.

The address decoder 1120 may be connected to the memory cell array 1110 through selection lines SSL and GSL and word lines WL1 to WLm. The address decoder 1120 may select a word line during a program or read operation. The address decoder 1120 may receive the word line voltage VWL from the word line voltage generator 1150 and provide a program voltage or read voltage to the selected word line.

The page buffer circuit 1130 may be connected to the memory cell array 1110 through bit lines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bit lines. Each page buffer may include a plurality of latches to store or read multi-bit data.

The input/output circuit 1140 may be internally connected to the page buffer circuit 1130 through data lines and externally connected to the memory controller (refer to FIG. 1, 1200) through the input/output lines IO1 to IOn. The input/output circuit 1140 may receive program data from the memory controller 1200 during a program operation. Also, the input/output circuit 1140 may provide data read from the memory cell array 1110 to the memory controller 1200 during a read operation.

The word line voltage generator 1150 may receive internal power from the control logic 1160 and generate a word line voltage VWL required to read or write data. The word line voltage VWL may be provided to a selected word line (sWL) or unselected word lines (uWL) through the address decoder 1120.

The word line voltage generator 1150 may include a program voltage generator 1151 and a pass voltage generator 1152. The program voltage generator 1151 may generate a program voltage Vpgm provided to the selected word line sWL during a program operation. The pass voltage generator 1152 may generate a pass voltage Vpass provided to the selected word line sWL and the unselected word lines uWL.

The word line voltage generator 1150 may include a read voltage generator 1153 and a read pass voltage generator 1154. The read voltage generator 1153 may generate a select read voltage Vrd provided to the select word line sWL during a read operation. The read pass voltage generator 1154 may generate a read pass voltage Vrdps provided to unselected word lines uWL. The read pass voltage Vrdps may be a voltage sufficient to turn on memory cells connected to the unselected word lines uWL during a read operation.

The control logic 1160 may control operations such as read, write, and erase of the memory device 1100 using commands CMD, addresses ADDR, and control signals CTRL provided from the memory controller 1200. The addresses ADDR may include a block selection address for selecting one memory block, a row address for selecting one page, and a column address for selecting one memory cell.

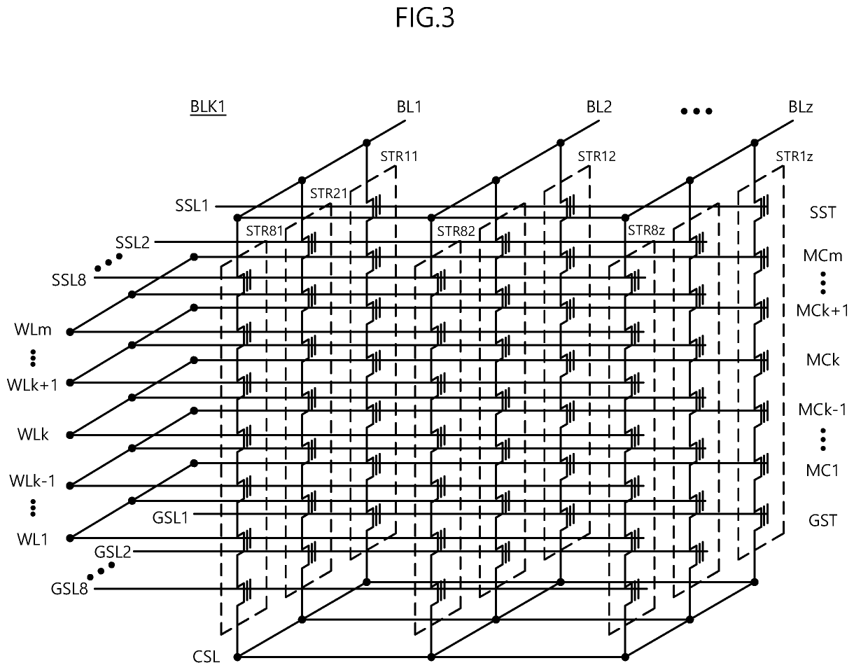

FIG. 3 is a circuit diagram illustrating an example embodiment of a memory block BLK1 of the memory cell array illustrated in FIG. 2. Referring to FIG. 3, in the memory block BLK1, a plurality of cell strings STR11 to STR8z may be formed between the bit lines BL1 to BLz and a common source line CSL. Each cell string includes a string selection transistor SST, a plurality of memory cells MC1 to MCm, and a ground selection transistor GST.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLz, and the ground selection transistors GST may be connected with the common source line CSL.

The first to m-th word lines WL1 to WLm may be connected with the plurality of memory cells MC1 to MCm in a row direction. The first to z-th bit lines BL1 to BLz may be connected with the plurality of memory cells MC1 to MCm in a column direction. First to z-th page buffers PB1 to PBz may be connected with the first to z-th bit lines BL1 to BLZ.

The first word line WL1 may be placed above the first to eighth ground selection lines GSL1 to GSL8. The first memory cells MC1 that are placed at the same height from the substrate may be connected with the first word line WL1. The second word line WL2 may be placed above the first word line WL1. The second memory cells MC2 that are placed at the same height from the substrate may be connected with the second word line WL2. In a similar manner, the third to m-th memory cells MC3 to MCm that are placed at the same heights from the substrate may be respectively connected with the third to m-th word lines WL3 to WLm.

The first word line WL1 may be placed above the first to eighth ground selection lines GSL1 to GSL8. The first memory cells MC1 that are placed at the same height from the substrate may be connected with the first word line WL1. The m-th word line WLm may be located below the first to eighth string selection lines SSL1 to SSL8. The m-th memory cells MCm located at the same height from the substrate may be connected to the m-th word line WLm. In a similar manner, the second to (m−1)-th memory cells MC2 to MCm−1 that are placed at the same heights from the substrate may be respectively connected with the second to (m−1)-th word lines WL2 to WLm−1, respectively.

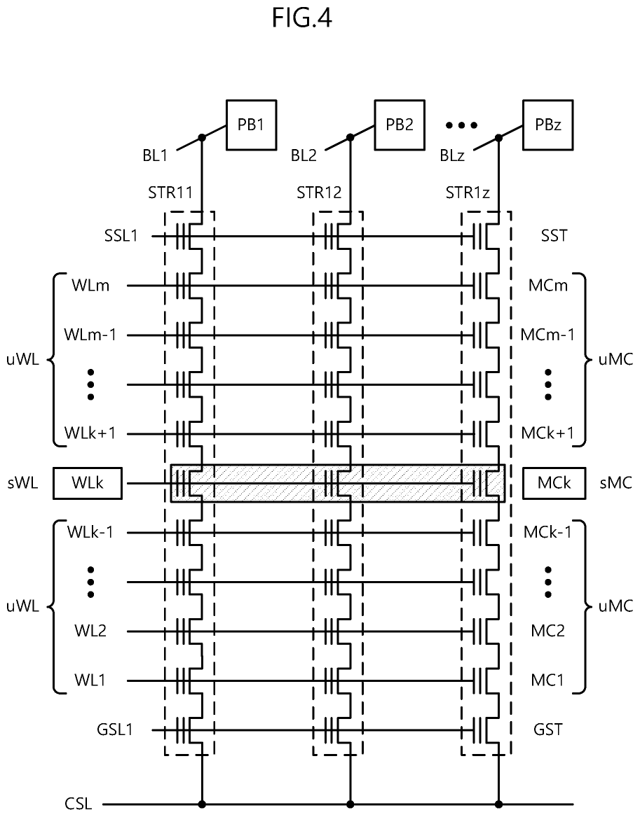

FIG. 4 is a circuit diagram illustrating cell strings selected by the first string selection line SSL1 from among the cell strings of the memory block BLK1 illustrated in FIG. 3. The 11th to 1z cell strings STR11 to STR1z may be selected by the first string selection line SSL1. The eleventh to 1z cell strings STR11 to STR1z may be connected to the first to z-th bit lines BL1 to BLz, respectively. The first to z-th page buffers PB1 to PBz may be connected to the first to z-th bit lines BL1 to BLz, respectively.

The eleventh cell string STR11 may be connected to the first bit line BL1 and the common source line CSL. The eleventh cell string STR11 may include string selection transistors SST selected by the first string selection line SSL1, first to m-th memory cells MC1 to MCm connected to the first to m-th word lines WL1 to WLm, and ground selection transistors GST selected by the first ground selection line GSL1. The twelfth cell string STR12 may be connected to the second bit line BL2 and the common source line CSL. The 1z cell string STR1z may be connected to the z-th bit line BLz and the common source line CSL.

The first word line WL1 and the m-th word line WLm may be edge word lines (edge WL). The second word line WL2 and the (m−1)-th word line WLm−1 may be edge adjacent word lines. The k-th word line WLk may be a selected word line sWL. The (k−1)-th word line WLk−1 and the (k+1)-th word line WLk+1 may be adjacent word lines adjacent to the selected word line. If the k-th word line WLk is the selected word line sWL, the remaining word lines WL1 to WLk−1 and WLk+1 to WLm may be unselected word lines uWL.

The first memory cells MC1 and the m-th memory cells MCm may be edge memory cells. The second memory cells MC2 and the (m−1)-th memory cells MCm−1 may be edge adjacent memory cells. The k-th memory cells MCk may be selected memory cells sMC. The (k−1)-th memory cells MCk−1 and the (k+1)-th memory cells MCk+1 may be memory cells adjacent to the selected memory cells (adjacent MC). If the k-th memory cells MCk are selected memory cells sMC, the remaining memory cells MC1 to MCk−1 and MCk+1 to MCm may be unselected memory cells uMC.

A set of memory cells selected by one string selection line and connected to one word line may be one page. For example, memory cells selected by the first string selection line SSL1 and connected to the k-th word line WLk may be one page. For example, eight pages may be configured on the k-th word line WLk. Among the eight pages, a page connected to the first string selection line SSL1 is a selected page, and pages connected to the second to eighth string selection lines SSL2 to SSL8 are unselected pages.

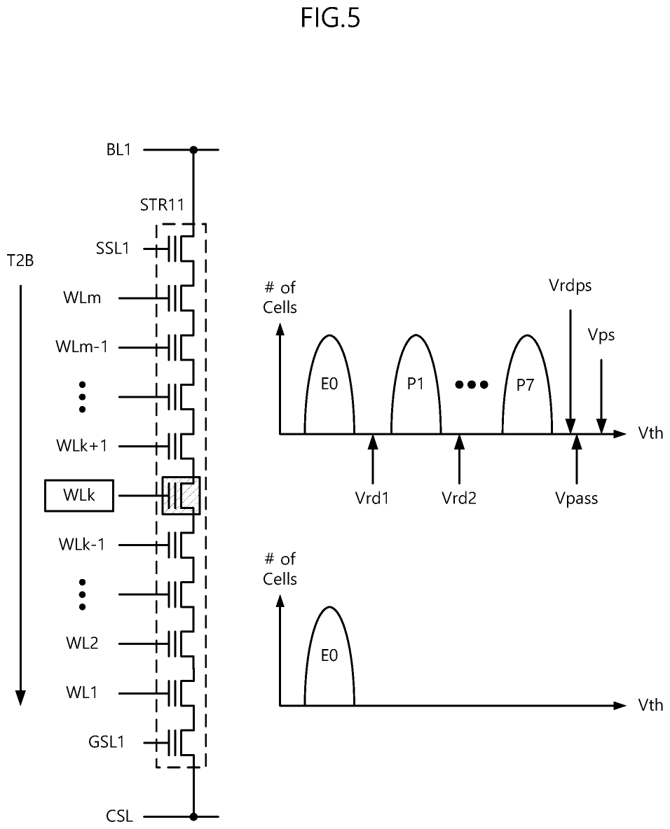

FIG. 5 is a diagram illustrating an example embodiment of threshold voltage distributions of memory cells illustrated in FIG. 4. The horizontal axis represents the threshold voltage Vth, and the vertical axis represents the number of memory cells.

FIG. 5 shows an example in which 3-bit data is stored in one memory cell. A 3-bit memory cell may have one of eight states (E0, P1 to P7) according to the threshold voltage distribution. E0 represents an erase state, and P1 to P7 represent program states.

During a read operation, the selection read voltages Vrd1 to Vrd7 may be provided to the selected word line sWL, and the pass voltage Vps and/or the read pass voltage Vrdps may be provided to the unselected word lines uWL. The pass voltage Vps and/or the read pass voltage Vrdps may be a voltage sufficient to turn on the memory cells. For example, the pass voltage Vps may be provided to the adjacent word lines WLk+1, and the read pass voltage Vrdps may be provided to the unselected word lines other than the adjacent word lines.

The first selection read voltage Vrd1 may be a voltage level between the erase state E0 and the first program state P1. The second selection read voltage Vrd2 may be a voltage level between the first and second program states P1 and P2. In this way, the seventh selection read voltage Vrd7 may be a voltage level between the sixth and seventh program states P6 and P7.

When the first selection read voltage Vrd1 is applied, the memory cell in the erase state E0 may be an on cell and the memory cell in the first to seventh program states P1 to P7 may be an off cell. When the second selection read voltage Vrd2 is applied, the memory cell in the erase state E0 and the first program state P1 may an on cell, and the memory cell in the second to seventh program states P2 to P7 may an off cell. In this way, when the seventh selection read voltage Vrd7 is applied, the memory cell in the erase state E0 and the first to sixth program states P1 to P6 may be an on cell and the memory cell in the seventh program state P7 may be an off cell.

During a read operation, the k-th word line WLk may be selected. A power supply voltage may be applied to the string selection line SSL1 and the ground selection line GSL1, and the string select transistor SST and the ground select transistor GST may be turned on. Also, the selection read voltage Vrd may be provided to the selected word line sWL, and the read pass voltage Vrdps and/or the pass voltage Vps may be provided to the unselected word lines uWL.

When the read operation of the k-th word line WLk is repeatedly performed, the high voltage read pass voltage Vrdps may be repeatedly provided to the remaining word lines. At this time, a read disturbance may occur in the remaining word lines, and thus the threshold voltage may be distorted. Memory cells connected to the k-th word line WLk may be off cells when a selection read voltage is provided. That is, when the threshold voltage of the k-th memory cell is higher than the selection read voltage, the k-th memory cell may be an off cell. When the k-th memory cell is an off cell, a channel may be separated at the k-th memory cell. That is, a lower channel of the k-th memory cell may receive a ground voltage from the common source line CSL, and an upper channel of the k-th memory cell may have a negative channel voltage Vneg.

A channel voltage difference may occur between a lower channel and an upper channel with the k-th memory cell interposed therebetween. Due to the channel voltage difference, hot carrier injection (HCI) may occur in an adjacent memory cells MCk+1 and/or MCk−1. For this reason, threshold voltages of memory cells connected to adjacent word lines WLk+1 and/or WLk−1 may be distorted. For example, the threshold voltages of memory cells in the erased state E0 may rise to enter the programmed state.

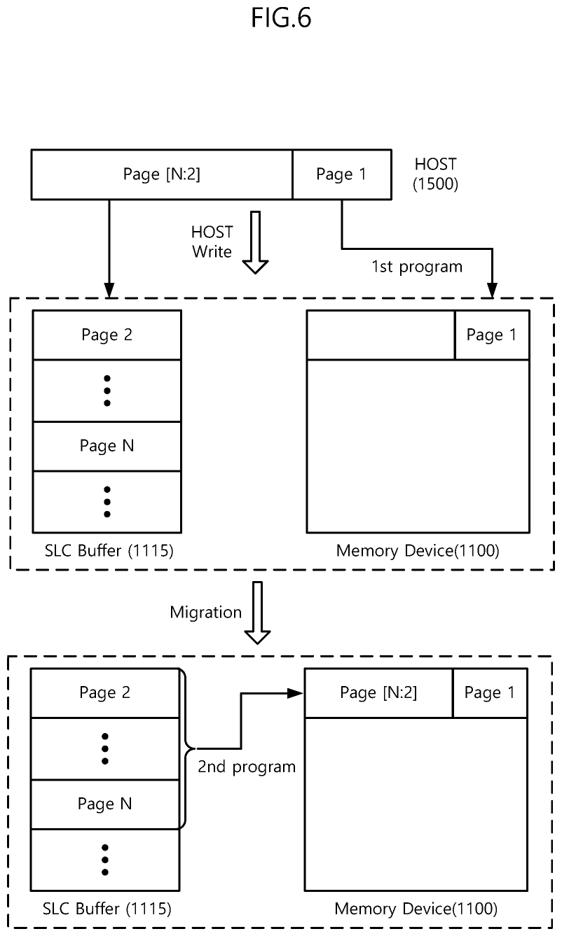

FIG. 6 is a conceptual diagram illustrating a method of operating the storage device shown in FIG. 1. Referring to FIGS. 1 and 6, the SLC buffering module 2000 may receive a write request for first to N-th pages from the host 1500 and perform a write operation on the storage device 1000. The write operation of the storage device 1000 may be largely divided into a host write operation and a migration operation.

During the host write operation, the SLC buffering module 2000 may perform a first program operation so that the first page is written in SLC format to an empty user block of the memory device 1100. The SLC buffering module 2000 may control the second to N-th pages to be written to the SLC buffer 1115.

During the migration operation, the SLC buffering module 2000 may perform a second program operation so that the second to N-th pages written in the SLC buffer 1115 are written to the user block of the memory device 1100.

The first to N-th pages may be written on one word line of the user block. Here, if N is 2, it may be called an MLC program. If N is 3, it may be called a TLC program. And if N is 4, it may be called a QLC program. In the case of a TLC program, three pages may be programmed in one word line, and 3 bit data may be stored in one memory cell.

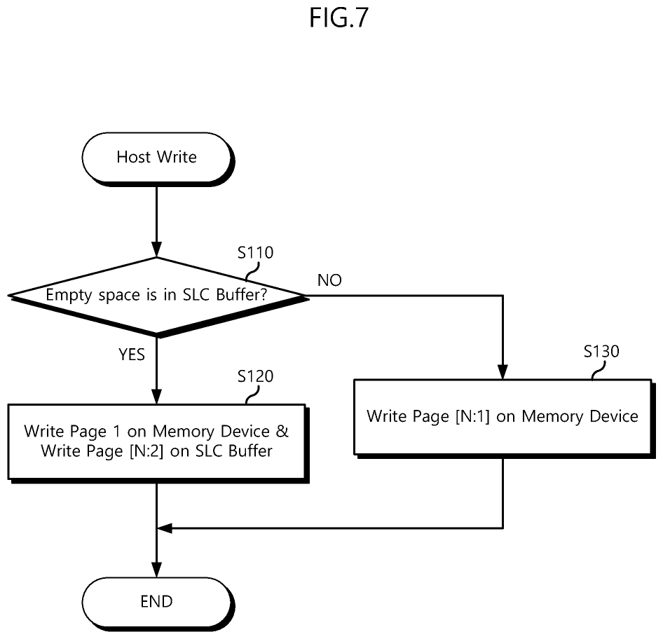

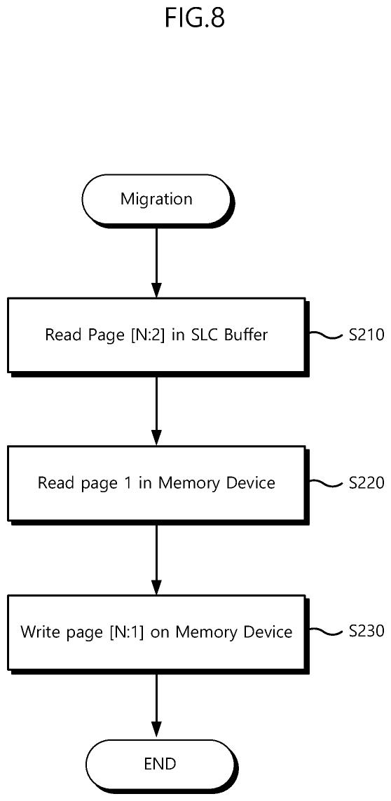

FIGS. 7 and 8 are flowcharts illustrating a method of operating the storage device shown in FIG. 6. FIG. 7 is a flowchart illustrating the host write operation of the SLC buffering module 2000, and FIG. 8 is a flowchart illustrating the migration operation of the SLC buffering module 2000.

Referring to FIG. 7, the SLC buffering module 2000 may receive a write request for first to N-th pages from the host 1500 and perform the host write operation.

In operation S110, the SLC buffering module 2000 may determine whether there is an empty space in the SLC buffer 1115. Here, the empty space may mean a data storage space that may be SLC programmed in the SLC buffer 1115. The SLC buffering module 2000 may determine whether there is a data storage space in the SLC buffer 1115 capable of storing the second to N-th pages. The SLC buffering module 2000 may perform operation S120 if there is empty space in the SLC buffer 1115 (YES), and may perform operation S130 if there is insufficient data storage space (NO).

In operation S120, the SLC buffering module 2000 may SLC program the first page to the memory device 1100. That is, the memory device 1100 may perform a first program operation to SLC program the first page to one word line of the user block. The SLC buffering module 2000 may program the second to N-th pages in the SLC buffer 1115. That is, the SLC buffer 1115 may program the second to N-th pages on N−1 word lines.

In operation S130, if the second to N-th pages cannot be stored in the SLC buffer 1115, the SLC buffering module 2000 may control the first to N-th pages to be written to the memory device 1100. That is, the memory device 1100 may program the first to N-th pages. If N is 3, the memory device 1100 may program three pages on one word line of the user block.

Referring to FIG. 8, the SLC buffering module 2000 may perform the migration operation after the host write operation is completed. The SLC buffering module 2000 may perform a second program operation so that the second to N-th pages written in the SLC buffer 1115 are written to the user block of the memory device 1100 during the migration operation.

In operation S210, the SLC buffering module 2000 may control a read operation of the SLC buffer 1115 through the buffer interface 1203. The SLC buffer 1115 may read the second to N-th pages under the control of the SLC buffering module 2000. The SLC buffer 1115 may provide the second to N-th pages to the memory device 1100 during idle time. According to example embodiments, the SLC buffer 1115 may provide the second to N-th pages to the memory device 1100 through the memory controller 1200 during idle time.

In operation S220, the SLC buffering module 2000 may control a read operation of the memory device 1100 through the memory interface 1202. The memory device 1100 may read the first page under the control of the SLC buffering module 2000. The memory device 1100 may store the first page in a page buffer circuit (see FIG. 2, 1130). The page buffer circuit 1130 may store second to N-th pages provided from the SLC buffer 1115.

In operation S230, the SLC buffering module 2000 may control a write operation of the memory device 1100 through the memory interface 1202. The memory device 1100 may perform a second program operation to program the first to N-th pages into the memory cell array 1110 under the control of the SLC buffering module 2000.

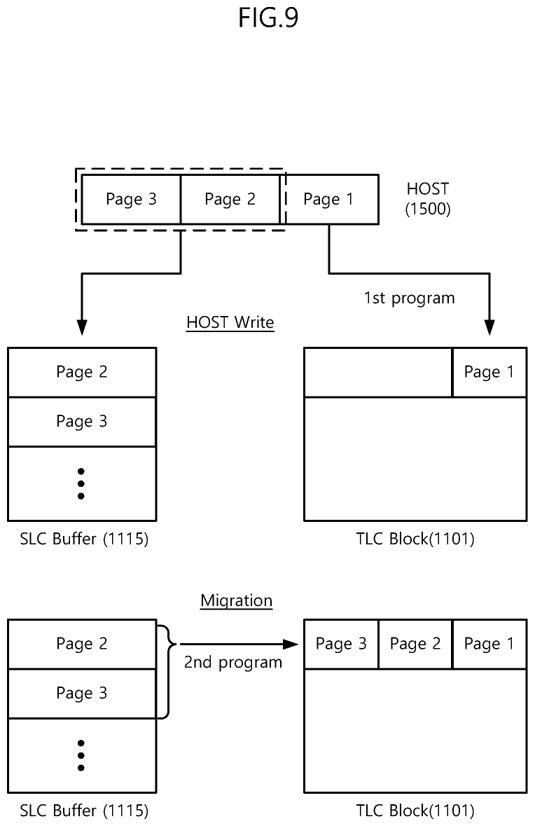

FIG. 9 is a conceptual diagram illustrating a TLC programming method of the storage device shown in FIG. 1. Referring to FIGS. 1 and 9, the SLC buffering module 2000 may receive a write request for the first to third pages from the host 1500 and perform a two-step program operation on the storage device 1000. In FIG. 9, the TLC block 1101 may be one memory block (e.g., BLK1 in FIG. 2) of the memory device 1100.

During a host write operation, the SLC buffering module 2000 may perform a first program operation so that the first page is written to the TLC block 1101 in SLC format. The SLC buffering module 2000 may control the second and third pages to be written to the SLC buffer 1115. During the migration operation, the SLC buffering module 2000 may perform a second program operation so that the second and third pages written to the SLC buffer 1115 are written to the TLC block 1101.

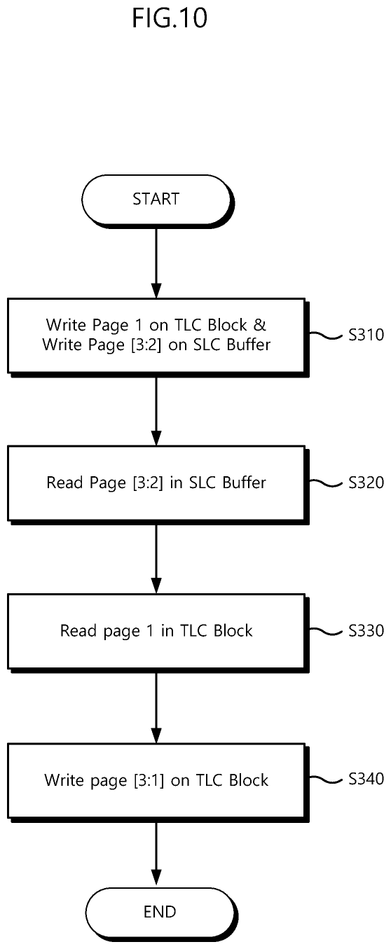

FIG. 10 is a flowchart illustrating a method of operating the storage device shown in FIG. 9. Referring to FIG. 10, the SLC buffering module 2000 may receive a write request for the first to third pages from the host 1500 and perform the host write operation and the migration operation of the storage device 1000.

In operation S310, the SLC buffering module 2000 may SLC program the first page in the TLC block 1101. That is, the memory device 1100 may perform a first program operation to SLC program the first page to one word line of the TLC block 1101. The SLC buffering module 2000 may program the second and third pages to the SLC buffer 1115.

The SLC buffering module 2000 may perform the migration operation after the host write operation is completed. The SLC buffering module 2000 may perform a second program operation so that the second and third pages written to the SLC buffer 1115 are written to the TLC block 1101 during the migration operation.

In operation S320, the SLC buffering module 2000 may control the read operation of the SLC buffer 1115. The SLC buffer 1115 may read the second and third pages under the control of the SLC buffering module 2000. The SLC buffer 1115 may provide the second and third pages to the TLC block 1101 during idle time.

In operation S330, the SLC buffering module 2000 may control a read operation of the memory device 1100. The memory device 1100 may read the first page of the TLC block 1101 under the control of the SLC buffering module 2000. The memory device 1100 may store the first page in a page buffer circuit (see FIG. 2, 1130). The page buffer circuit 1130 may store the second and third pages provided from the SLC buffer 1115.

In operation S340, the SLC buffering module 2000 may control a write operation of the memory device 1100. The memory device 1100 may perform a second program operation to program the first to third pages to the memory cell array 1110 under the control of the SLC buffering module 2000.

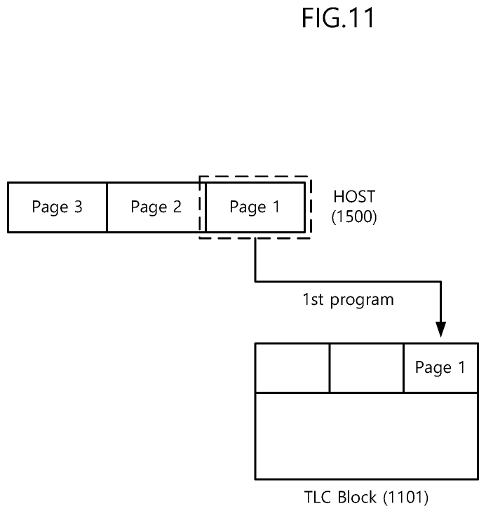

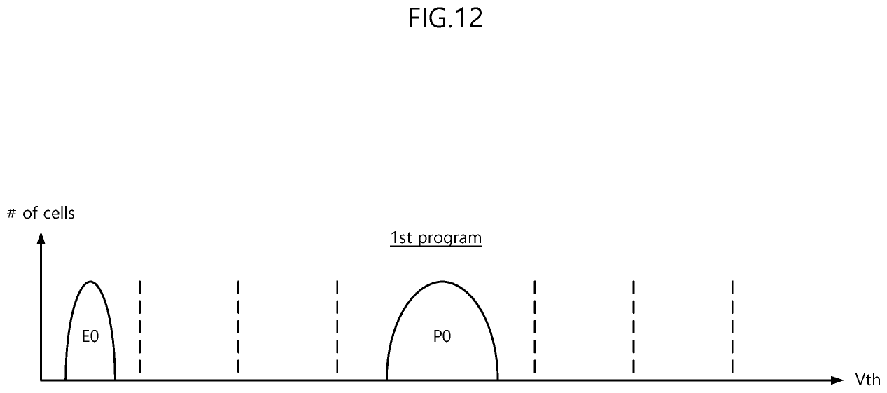

FIGS. 11 and 12 are diagrams illustrating an example embodiment of the first program operation shown in FIG. 9 and threshold voltage distribution. Referring to FIG. 11, the SLC buffering module 2000 may SLC program the first page in the TLC block 1101. That is, the memory device 1100 may SLC program the first page to one word line of the TLC block 1101 during the first program operation. The programmed memory cells may be referred to as first memory cells.

Referring to FIG. 12, the memory device (see FIG. 1, 1100) may have an erase state (E0) and one program state (P0) as a result of the first program operation. According to the threshold voltage distribution resulting from the first program operation, the memory device 1100 may have sufficient read margin between the erase state (E0) and the program state (P0).

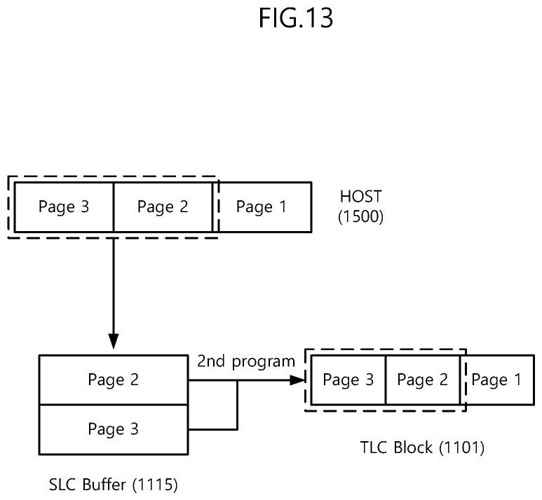

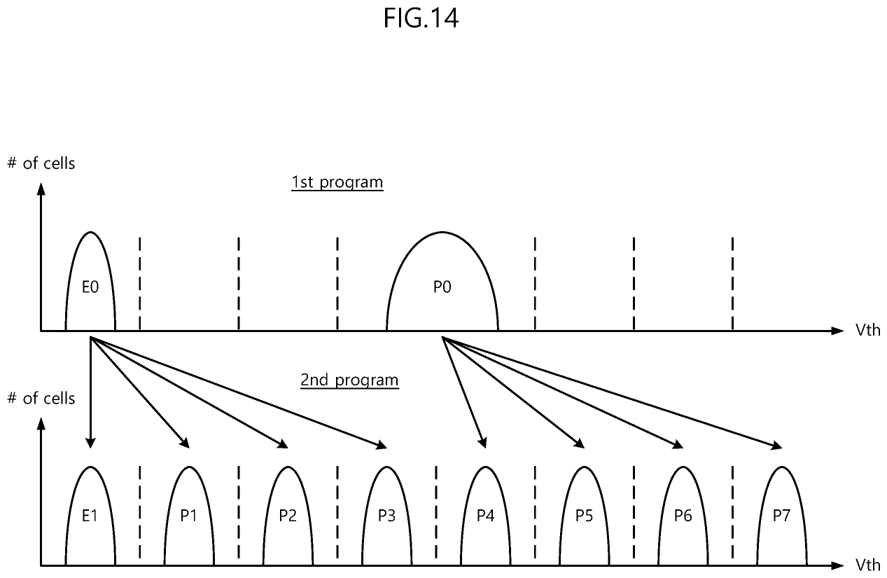

FIGS. 13 and 14 are diagrams illustrating an example embodiment of the second program operation shown in FIG. 9 and threshold voltage distribution. Referring to FIG. 13, the SLC buffering module 2000 may program the second and third pages to the SLC buffer 1115.

The SLC buffering module 2000 may perform the migration operation after the host write operation is completed. The SLC buffering module 2000 may perform a second program operation so that the second and third pages written to the SLC buffer 1115 are written to the TLC block 1101 during the migration operation.

Referring to FIG. 14, the memory device (see FIG. 1, 1100) may have an erase state (E0) and one program state (P0) as a result of the first program operation. During the migration operation, the SLC buffering module 2000 may provide the second and third pages written in the SLC buffer 1115 to the TLC block 1101.

The memory device 1100 may perform a second program operation to program the first to third pages into the TLC block 1101 under the control of the SLC buffering module 2000. The erase state (E0) of the first program operation may become the erase state (E1) and the first to third program states (P1, P2, and P3) as a result of the second program operation. That is, the memory cell that was in the erase state (E0) due to the first program operation may have any one of the erase state (E1) and the first to third program states (P1, P2, and P3) as a result of the second program operation.

The program state (P0) of the first program operation may be the fourth to seventh program states (P4 to P7) as a result of the second program operation. That is, the memory cell that was in the program state (P0) due to the first program operation may have any one of the fourth to seventh program states (P4 to P7) as a result of the second program operation.

In one or more embodiments, each of the first memory cells is in one of an first erase state (E0), with a first erase read level voltage distribution (see FIG. 14) and a first program state (P0) with a first program read level voltage distribution (see FIG. 14).

In one or more embodiments, based on the second program operation, each of the first memory cells initially in the first erase state, (E0), is in one of an erase state (E1) (see FIG. 14) or first to third program states (P1 to P3), which may be referred to as a second program state, a third program state or a fourth program state, respectively.

In one or more embodiments, based on the second program operation, each of the first memory cells initially in the first program state, (P0), is in one of a fifth program state, a sixth program state, a seventh program state or an eighth program state, respectively (see the fourth to seventh program states (P4 to P7) in FIG. 14).

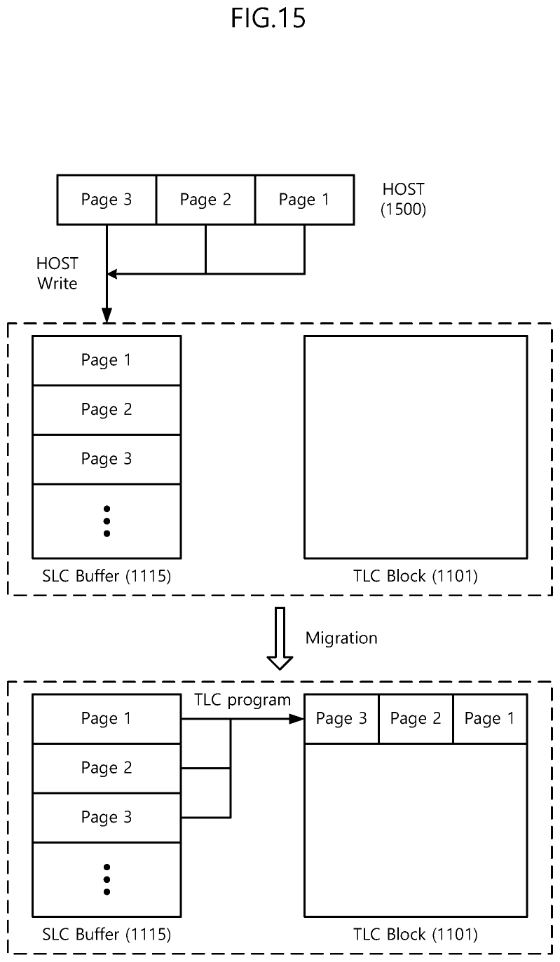

FIG. 15 is a conceptual diagram illustrating another example embodiment of a TLC program operation of the storage device shown in FIG. 1. Referring to FIG. 15, during the host write operation, the storage device 1000 may receive a write request for first to third pages from the host 1500 and program the first to third pages in the SLC buffer 1115. During the migration operation, the storage device 1000 may TLC program the first to third pages stored in the SLC buffer 1115 to one word line of the TLC block 1101.

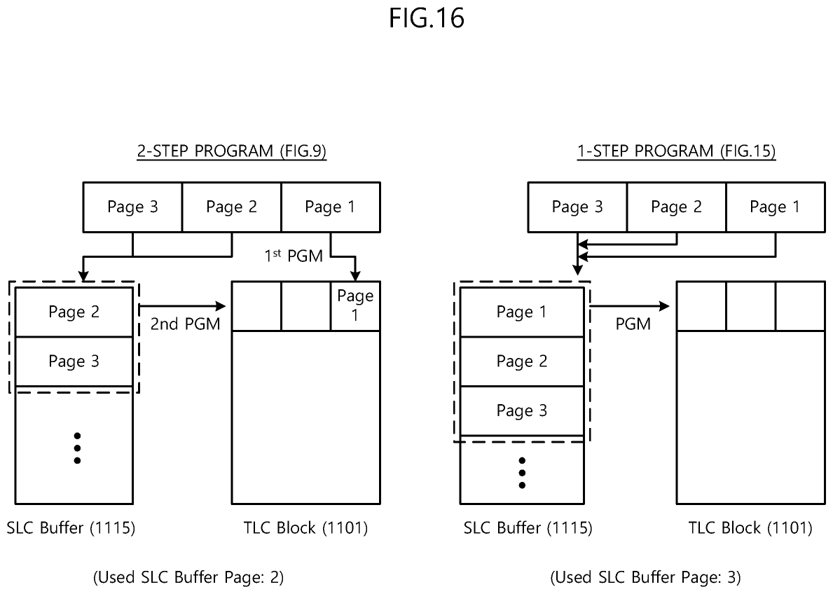

FIG. 16 is a conceptual diagram illustrating the difference between the TLC program method shown in FIG. 9 and the TLC program method shown in FIG. 15. The program method shown in FIG. 9 is a two-step program method, and the program method shown in FIG. 15 is a one-step program method.

The TLC program method shown in FIG. 9 may include a first program operation to write the first page to the TLC block 1101 during the host write operation, and a second program to write the second and third pages to the TLC block 1101 during the migration operation. The TLC program method shown in FIG. 15 may write the first to third pages to the SLC buffer 1115 during the host write operation and write the first to third pages to the TLC block 1101 during the migration operation.

The two-step program method of FIG. 9 may use two pages of the SLC buffer 1115 when performing a TLC program, while the one-step program method of FIG. 15 may use 3 pages of the SLC buffer 1115. According to the two-step program method of FIG. 9, page usage of the SLC buffer 1115 may be reduced by about 33% compared to the one-step program method of FIG. 15.

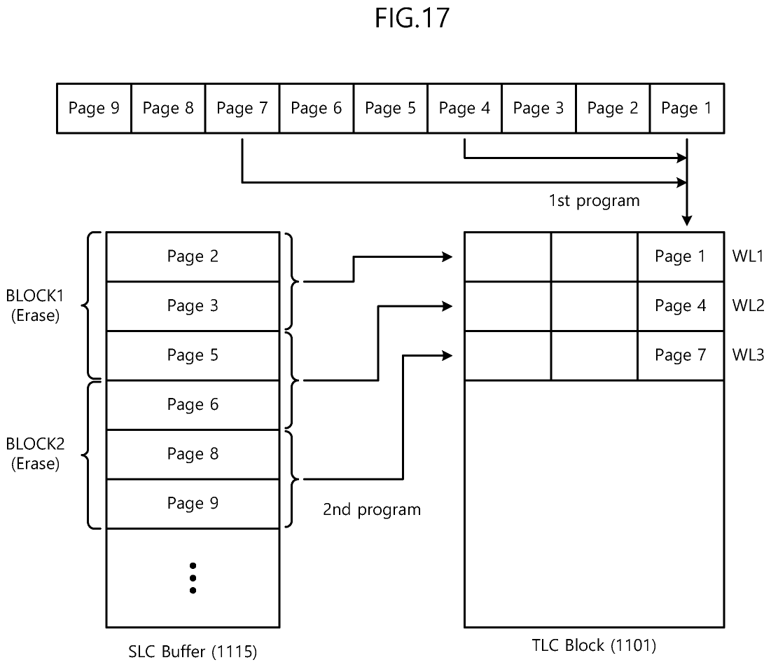

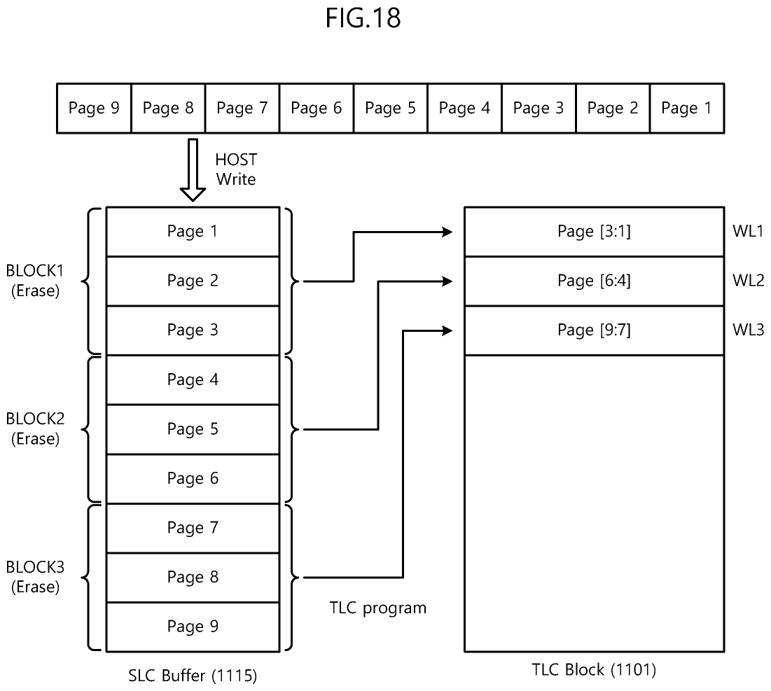

FIGS. 17 and 18 are conceptual diagrams illustrating another example embodiment of the difference between the TLC program method shown in FIG. 9 and the TLC program method shown in FIG. 15. FIG. 17 shows a method of performing a TLC program using the two-step program method shown in FIG. 9. FIG. 18 shows a method of performing a TLC program using the one-step program method shown in FIG. 15.

FIGS. 17 and 18, it is assumed that the storage device 1000 receives a write request for the first to ninth pages from the host 1500. Also, it is assumed that one block consists of three pages, and the size of each page is the same.

Referring to FIG. 17, the storage device 1000 may perform a first program operation to write the first page, fourth page, and seventh page to the TLC block 1101 during the host write operation. The first page may be SLC programmed to the first word line WL1, the fourth page may be SLC programmed to the second word line WL2, and the seventh page may be SLC programmed to the third word line WL3. The storage device 1000 may write the remaining pages to the SLC buffer 1115.

The storage device 1000 may perform a second program operation to write the remaining pages to the TLC block 1101 during the migration operation. The second and third pages may be TLC programmed to the first word line WL1. The fifth and sixth pages may be TLC programmed to the second word line WL2. And the eighth and ninth pages may be TLC programmed to the third word line WL3.

After performing the first and second program operations, the storage device 1000 may erase the first and second blocks BLOCK1 and BLOCK2 of the SLC buffer 1115. The first block (BLOCK1) may be composed of a second page, a third page, and a fifth page. The second block (BLOCK2) may be composed of the 6th page, the 8th page, and the 9th page. According to the two-step program method shown in FIG. 17, two blocks of the SLC buffer 1115 may be erased after the TLC program operation.

Referring to FIG. 18, the storage device 1000 may write the first to ninth pages to the SLC buffer 1115 during the host write operation. The storage device 1000 may TLC program the first to ninth pages to the TLC block 1101 during the migration operation. The first to third pages may be TLC programmed to the first word line WL1. The fourth to sixth pages may be TLC programmed to the second word line WL2. And the seventh to ninth pages may be TLC programmed to the third word line WL3.

After performing the TLC program operation, the storage device 1000 may erase the first to third blocks BLOCK1, BLOCK2, and BLOCK3 of the SLC buffer 1115. The first block (BLOCK1) is composed of the first to third pages, the second block (BLOCK2) is composed of the fourth to sixth pages, and the third block (BLOCK3) is composed of the seventh to ninth pages. According to the one-step program method shown in FIG. 18, three blocks of the SLC buffer 1115 may be erased after the TLC program operation.

The two-step program method of FIG. 17 may erase two blocks of the SLC buffer 1115 when performing a TLC program, while the one-step program method of FIG. 18 may erase three blocks of the SLC buffer 1115. According to the two-step program method of FIG. 17, block erase of the SLC buffer 1115 may be reduced by about 33% compared to the one-step program method of FIG. 18.

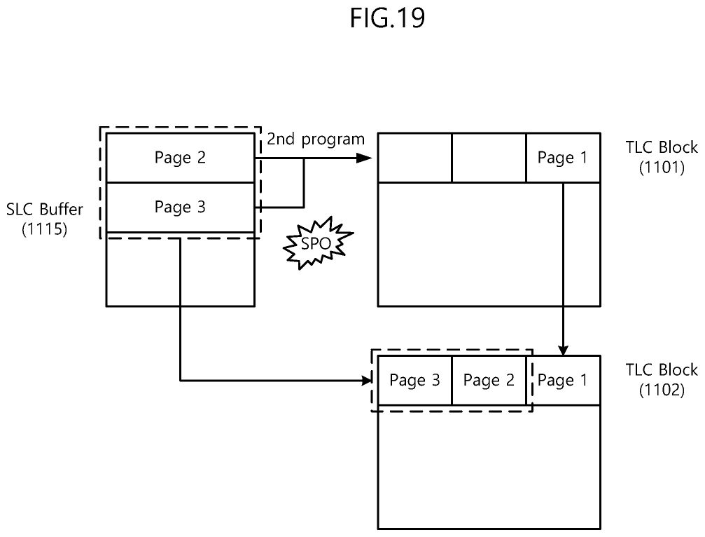

FIG. 19 is a conceptual diagram illustrating a data recovery method when a sudden power-off occurs during a second program operation of the storage device shown in FIG. 9. Referring to FIGS. 1 and 19, the SLC buffering module 2000 may receive a write request for the first to third pages from the host 1500 and perform a two-step program operation to the storage device 1000.

During the host write operation, the SLC buffering module 2000 may perform a first program operation so that the first page is written to the first TLC block 1101 in SLC format. The SLC buffering module 2000 may control the second and third pages to be written to the SLC buffer 1115. During the migration operation, the SLC buffering module 2000 may perform a second program operation so that the second and third pages written to the SLC buffer 1115 are written to the first TLC block 1101.

A sudden power off (SPO) situation may occur during the second program operation. That is, an SPO situation may occur while the first page is written to the first TLC block 1101 and the second and third pages are written to the first TLC block 1101. Even if an SPO situation occurs, the storage device 1000 may restore the first to third pages. This is because the first page is data written with sufficient read margin during the first program operation, and the second and third pages are stored in the SLC buffer 1115.

In an SPO situation, the SLC buffering module 2000 may move the first page written to the first TLC block 1101 and the second and third pages stored in the SLC buffer 1115 to the second TLC block 1102. The storage device 1000 may read all first to third pages under the control of the SLC buffering module 2000 and then TLC program the first to third pages in the second TLC block 1102.

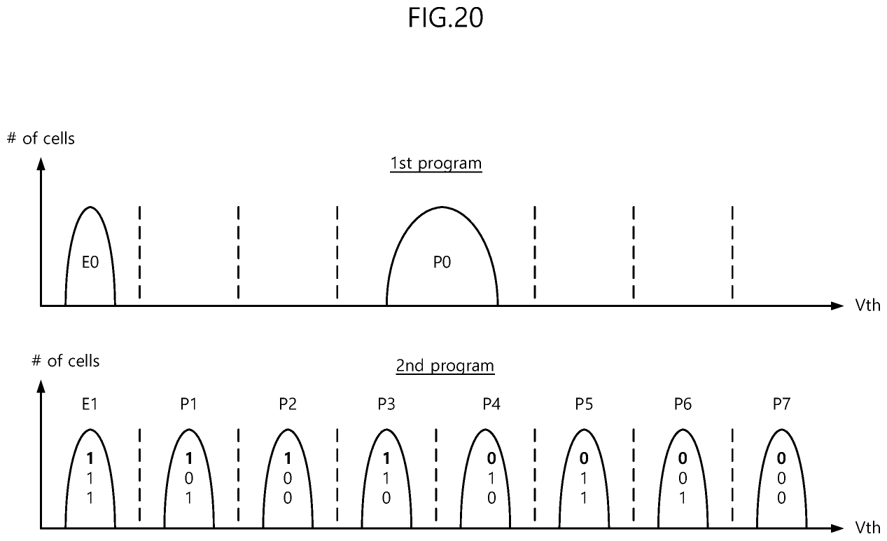

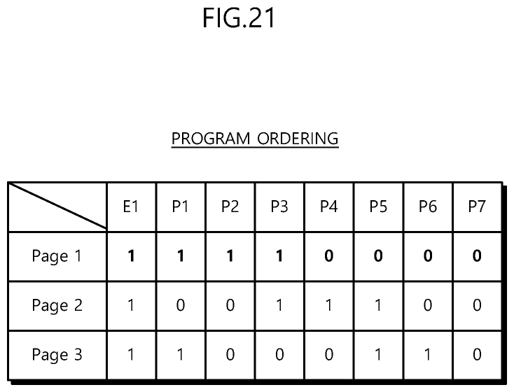

FIGS. 20 and 21 are graph and diagram illustrating threshold voltage distribution and program ordering of a storage device that performs a two-step program operation. Referring to FIG. 20, the storage device 1000 may have an erase state (E0) and one program state (P0) as a result of the first program operation.

The erase state (E0) of the first program operation may become the erase state (E1) and the first to third program states (P1, P2, and P3) as a result of the second program operation. The program state (P0) of the first program operation may become the fourth to seventh program states (P4 to P7) as a result of the second program operation. That is, the memory cell may have one of the erase state (E1) and the first to seventh program states (P1 to P7) as a result of the second program operation.

The erase state (E1) and the first to seventh program states (P1 to P7) may have program ordering as shown in FIG. 21. That is, the erase state (E1) may be 1,1,1, the first program state (P1) may be 1,0,1, the second program state (P2) May 1,0,0, and the third program state (P3) may be 1,1,0, the fourth program state (P4) may be 0,1,0, the fifth program state (P5) may be 0,1,1, and the sixth program state (P6) may be 0,0,1, and the seventh program state (P7) may be 0,0,0.

When memory cells have the program ordering shown in FIG. 21, the first page written to the first TLC block 1101 may have sufficient read margin, and data may be easily recovered even if a sudden power-off situation occurs.

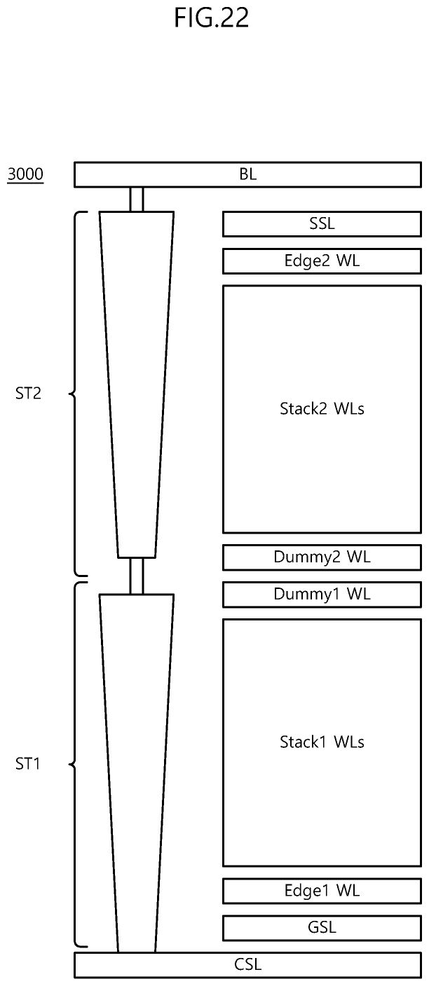

FIG. 22 is a diagram illustrating an example embodiment of a flash memory having a multi-stack structure. Referring to FIG. 22, the flash memory 3000 may have a first stack ST1 and a second stack ST2. The first stack ST1 may be located at the bottom, and the second stack ST2 may be located at the top.

A pillar of the flash memory 3000 may be formed by bonding the first and second stacks ST1 and ST2. A plurality of dummy word lines (e.g., Dummy 1 WL and Dummy2 WL) may be included at junctions of the first and second stacks ST1 and ST2. The first stack ST1 may be positioned between the common source line CSL and the first dummy word line Dummy1 WL. The second stack ST2 may be positioned between the second dummy word line Dummy2 WL and the bit line BL.

The first stack ST1 may include a ground selection line GSL, a first edge word line Edge1 WL, and first stack word lines Stack1 WLs. The second stack ST2 may include second stack word lines Stack2 WLs and second edge word lines Edge2 WL. Memory cells connected to the first and second edge word lines Edge1 WL and Edge2 WL may store bit data different from the other memory cells. For example, memory cells connected to the first and second edge word lines Edge1 WL and Edge2 WL may be SLC or MLC, and memory cells connected to the other word lines may be TCL or QLC. The flash memory 3000 may move the TLC block in the first stack (ST1) to the TLC block in the second stack (ST2) during sudden power-off.

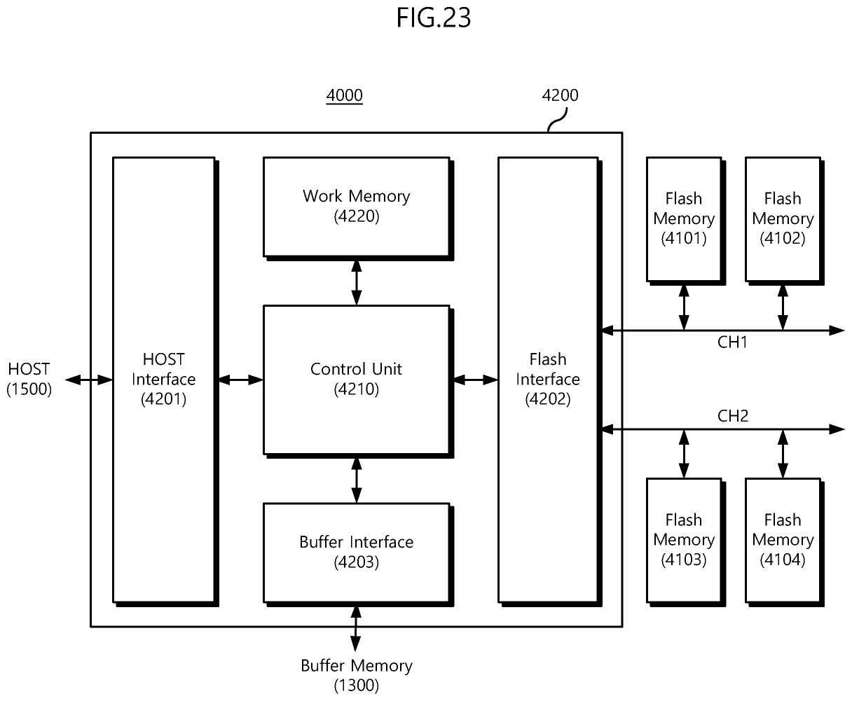

FIG. 23 is a block diagram illustrating an example in which a storage device according to an embodiment of the present disclosure is implemented with a solid state drive (SSD). Referring to FIG. 23, an SSD 4000 may include a plurality of flash memories 4101 to 4104 and an SSD controller 4200.

The first and second flash memories 4101 and 4102 may be connected with the SSD controller 4200 through a first channel CH1. The third and fourth flash memories 4103 and 4104 may be connected with the SSD controller 4200 through a second channel CH2. The number of channels connected with the SSD controller 4200 may be 2 or more. The number of flash memories connected with one channel may be 2 or more.

The SSD controller 4200 may include a host interface 4201, a flash interface 4202, a buffer interface 4203, a control unit 4210, and a work memory 4220. The SSD controller 4200 may be connected with a host 1500 through the host interface 4201. Depending on a request of the host 1500, the SSD controller 4200 may write data in the corresponding flash memory or may read data from the corresponding flash memory.

The SSD controller 4200 may be connected with the plurality of flash memories 4101 to 4104 through the flash interface 4202 and may be connected with a buffer memory 1300 through the buffer interface 4203. The flash interface 4202 may provide data, which are temporarily stored in the buffer memory 1300, to the flash memories through the channels CH1 and CH2. The flash interface 4202 may transfer the data read from the flash memories 4101 to 4104 to the buffer memory 1300.

The control unit 4210 may analyze and process the signal received from the host 1500. The control unit 4210 may control the host 1500 or the flash memories 4101 to 4104 through the host interface 4201 or the flash interface 4202. The control unit 4210 may control operations of the flash memories 4101 to 4104 by using firmware for driving the SSD 4000.

The SSD controller 4200 may manage data to be stored in the flash memories 4101 to 4104. In the sudden power-off event, the SSD controller 4200 may back the data stored in the work memory 4220 or the buffer memory 1300 up to the flash memories 4101 to 4104.

While the present disclosure has been described with reference to example embodiments thereof, it will be apparent to those of ordinary skill in the art that various changes and modifications may be made thereto without departing from the spirit and scope of the present disclosure as set forth in the following claims.

What is claimed is:

1. A storage device comprising:
a memory device configured to store data;
a single-level cell (SLC) buffer configured temporarily to store data to be stored in the memory device; and
a memory controller configured to control read operations or write operations of the memory device and the SLC buffer,
wherein the memory controller is further configured to:
perform a first program operation to SLC program a first page to first memory cells of the memory device based on a host write request,
store at least one second page to the SLC buffer, and
perform, during an idle time, a second program operation of programming the at least second page stored in the SLC buffer to the first memory cells.

2. The storage device of claim 1, wherein the memory device comprises flash memory, and
wherein the memory controller is further configured to SLC program the first page during the first program operation, and triple-level cell (TLC) program the first page and the at least second page during the second program operation.

3. The storage device of claim 2, wherein the SLC buffer comprises flash memory, and
wherein the memory controller is further configured to SLC program the at least second page to the SLC buffer.

4. The storage device of claim 1, wherein the memory controller is further configured to:
determine whether an empty storage space exists in the SLC buffer to store the at least second page, and
based on determining there is the empty storage space exists, store the first page in the memory device and store the at least second page in the SLC buffer.

5. The storage device of claim 4, wherein the memory controller is further configured to, based on determining the empty storage space does not exist, store the first page and the at least second page to the memory device.

6. The storage device of claim 1, wherein each of the first memory cells is in one of an first erase state with a first erase read level voltage distribution and a first program state with a first program read level voltage distribution.

7. The storage device of claim 6, wherein, based on the second program operation, each of the first memory cells initially in the first erase state is in one of a second erase state, a second program state, a third program state or a fourth program state.

8. The storage device of claim 7, wherein, based on the second program operation, each of the first memory cells initially in the first program state is in one of a fifth program state, a sixth program state, a seventh program state or an eighth program state.

9. The storage device of claim 8, wherein the memory controller is further configured to, based on a sudden power-off occurring while performing the second program operation, move the first page stored in a first memory block of the memory device and at least second page stored in the SLC buffer to a second memory block.

10. The storage device of claim 9, wherein the second memory block is another memory device different from the memory device.

11. A memory controller that controls an operation of a memory device and a single-level cell (SLC) buffer, the memory controller comprising:
a first interface connected to a host;
a second interface connected to the memory device; and
a third interface connected to the SLC buffer,
wherein the memory controller is further configured to:
receive a write request from the host through the first interface,
SLC program a first page to first memory cells of the memory device through the second interface,
store at least second page to the SLC buffer through the third interface, and
program the at least second page stored in the SLC buffer to the first memory cells during an idle time.

12. The memory controller of claim 11, wherein each of the at least second page is programmed using a triple-level cell (TLC) program to the first memory cells.

13. The memory controller of claim 12, wherein the memory controller is further configured to:
determine whether an empty storage space exists in the SLC buffer for storing the at least second page, and
based on determining the empty storage space exists, SLC program the first page to the memory device, and store the at least second page to the SLC buffer.

14. The memory controller of claim 13, wherein the memory controller is further configured to, based on determining the empty storage space does not exist, store the first page and the at least second page to the memory device.

15. The memory controller of claim 12, wherein each of the first memory cells is in one of a first erase state with a first erase read level voltage distribution and a first program state with a first program read level voltage distribution.

16. The memory controller of claim 15, wherein, based on the TLC program, each of the first memory cells initially in the first erase state is in one of a second erase state, a second program state, a third program state or a fourth program state.

17. The memory controller of claim 16, wherein, based on the TLC program, each of the first memory cells initially in the first program state is in one of a fifth program state, a sixth program state, a seventh program state or an eighth program state.

18. The memory controller of claim 17, wherein the memory controller is further configured to, based on a sudden power-off occurring while performing the TLC program, control to store the first page stored in a first memory block of the memory device and the at least second page stored in the SLC buffer to a second memory block.

19. A method for operating a storage device which comprises a memory device for storing data, a single-level cell (SLC) buffer configured to temporarily store data to be stored in the memory device, and a memory controller configured to control read operations or write operations of the memory device and the SLC buffer, the method comprising:
receiving a write request from a host and SLC programming a first page to first memory cells of the memory device;
storing, to the SLC buffer, at least second page; and
triple-level cell (TLC) programming the at least second page stored in the SLC buffer to the first memory cells during an idle time.

20. The method of claim 19, further comprising, based on a sudden power-off occurring while performing the TLC programming, storing the first page stored in a first memory block of the memory device and the at least second page stored in the SLC buffer to a second memory block.
